(19) United States
(12) Patent Application Publication
(10) Pub. No.: US 2026/0029498 A1
(43) Pub. Date: Jan. 29, 2026

(54) Method and Device for Determining a Correction for an Energy Measurement in an Inductive Charging System

(71) Applicant: BRUSA ELEKTRONIK AG, Buchs (CH)

(72) Inventors: Lukas Böhler, Wangs (CH); Thomas Thomsen, Taufkirchen (DE)

(21) Appl. No.: 19/111,929

(22) PCT Filed: Sep. 18, 2023
(86) PCT No.: PCT/EP2023/075662

§ 371 Date: Mar. 14, 2025

(30) Foreign Application Priority Data
Sep. 19, 2022 (DE) 10 2022 123 999.3

(51) Int. Cl. G01R 35/00; G01R 21/133; G01R 33/02

(52) U.S. Cl. CPC G01R 35/005; G01R 21/133; G01R 33/02

(57) ABSTRACT

A compensation device and a method of determining a correction value in a primary-side charging plate during the measurement of energy for a secondary charging plate, the method including: selecting at least one component that has an error or loss in the primary-side charging plate, wherein the at least one component that has an error or loss is influenced by at least one error or loss selected from the group of errors consisting of a measurement error (P_{GA,err}) with respect to a comparison value, an intrinsic loss (Pᵢₙₜᵣ), and a measurement loss (P_{MVA,err}) of the secondary charging plate; determining an overall correction factor of the respective measurement errors or losses of the at least one component that has an error or loss; determining an overall correction factor and writing the overall correction factor as a correction value to a storage unit of the primary-side charging plate.

### CROSS REFERENCE TO RELATED APPLICATIONS

The present application is the U.S. National Phase of PCT/EP2023/075662, filed on 18 Sep. 2023, which claims priority to German Patent Application No. 10 2022 123 999.3, filed on 19 Sep. 2022, the entire contents of which are incorporated herein by reference.

### FIELD OF THE INVENTION

The invention relates to the technical field of inductive charging. In particular, the present invention relates to methods for determining a measurement error, a compensation device for determining a measurement error, a method for error-corrected measurement of energy provided to a secondary-side charging plate, a primary-side charging plate for error-corrected measurement of energy provided to a secondary-side charging plate, and a measuring probe for magnetic field measurement.

### BACKGROUND OF THE INVENTION

For the electrical charging of a purely electric vehicle (EV) or a hybrid vehicle (PHEV, Plug-in Hybrid-Electric Vehicle), which is powered by a combination of fuel and electrical energy, an inductive energy transfer system can be used if charging is to be carried out in a contactless manner. In such a system, an alternating magnetic field is generated in the frequency range of 25 . . . 150 kHz. It should be noted that outside this frequency band the limits for the emission of electromagnetic waves are defined by internationally valid standards. Although in principle a magnetic field is used to transfer energy, the fact that the magnetic field changes means that it is inherently an electromagnetic wave. However, due to the frequency of the alternating magnetic field, the electromagnetic wave used in inductive charging has a wavelength of several kilometers.

As a coupling element for the energy transfer, a primary-side charging plate (Ground Assembly, GA) with a primary coil is used on the stationary side and a secondary-side charging plate (Vehicle Assembly, VA) with a secondary coil is used on the vehicle side. GA and VA form a transformer for coupling and energy transfer. The physical alignment of the coupling elements to each other is measured and adjusted, for example, via a positioning signal. Different transmission technologies with different frequencies are used for the energy transfer and the transmission of the positioning signal.

For example, inductive charging systems use the GA and VA to charge the vehicle battery of an electric vehicle with electrical energy while it is parked. The primary-side of the inductive charging system is usually the side operated by an energy supply company. During charging, electrical energy on the primary side is converted into an alternating magnetic field and transferred to the secondary-side. The secondary-side is usually the consumer side, in particular, the customer of the energy supplier. On the secondary side, the alternating magnetic field is converted back into electrical energy in the form of direct current to charge the vehicle battery.

However, if the inductive charging system is operated as a charging station in a public space and the customer consequently purchases and pays for the energy supplied from the charging station operator, in particular, the energy supply company, then there are legal requirements according to which the measurement of the electrical energy supplied must be carried out by a calibrated device.

For example, in Europe there is the EU Directive 2014/32/EU called “Measurement Instrument Directive” (MID). It is implemented into German law through the Measurement and Calibration Act (MessEG) and the Measurement and Calibration Ordinance (MessEV).

European and German calibration law defines requirements for the calibration of measuring instruments. The requirements are essentially defined as requirements regarding error limits, reproducibility, repeatability, response threshold and sensitivity, durability, reliability and suitability.

The aim of the requirements is to protect consumers from inaccurate measurements. When measuring consumption, this also includes ensuring that the person responsible for the loss of performance, such as the consumer of the energy, has his or her consumption correctly attributed to him or her. This is intended to guarantee correct billing and exact payment for the amount of energy used by the consumer.

### SUMMARY OF THE INVENTION

It can be considered to be an object of the present invention to enable effective determination of an energy amount.

Accordingly, a method for determining a correction value, a correction and/or a measurement error, a compensation device for determining a correction value and/or a measurement error, a method for error-corrected and/or measured energy provided for a secondary-side charging plate, a primary-side charging plate for error-corrected and/or calibrated measurement of the energy provided for a secondary-side charging plate and a measuring probe for magnetic field measurement are specified.

The subject matter of the invention is specified by the features of the independent claims. Example embodiments and further aspects of the invention are specified by the dependent claims and the following description.

According to one aspect of the present invention, a method is provided for determining a correction value, a correction and/or measurement error for an energy measurement in a primary-side charging plate when providing energy to a secondary charging plate. The method comprises selecting at least one component to be corrected and/or having an error in the primary-side charging plate, wherein the at least one component to be corrected and/or having an error is influenced by at least one disturbance factor and/or an error selected from the group of disturbance factors consisting of a measurement error with respect to a comparison value, an intrinsic partial measurement error and/or intrinsic partial loss, an intrinsic measurement error and/or intrinsic loss and a reaction measurement error and/or reaction measurement loss from the secondary charging plate.

The method further comprises determining an overall disturbance factor of the respective disturbance factors of the at least one component to be corrected and/or the at least one component having an error and determining the correction value from the overall disturbance factor and/or the overall measurement error, as well as writing the overall disturbance factor as a correction value to a storage unit of the primary-side charging plate.

The method can be used as a method for regulatory calibration and/or calibrating an integrated electricity meter in an inductive charging system. The integrated electricity meter may be implemented using sensors and/or measuring points built into the inductive charging system.

By use of calibrated reference measuring devices, deviations from measurements in the primary-side charging plate and/or the secondary-side charging plate with respect to standardized comparison values can be determined and thus taken into account as correction values in future measurements in order to compensate for corresponding errors.

According to one aspect, a technical possibility of measuring the amount of energy transmitted may be described, which can meet the requirements of European and German calibration law.

According to another aspect of the present invention, the correction value forms a correction curve.

The correction values can be individual values or form a correction curve or a compensation curve over a predeterminable range. The individual values and/or the correction curve can be represented and provided, for example, as a first-order polynomial or as conversion tables.

The correction and/or the correction values may have values that are added together to form an overall value. The correction may be a constant, but it can also be a characteristic curve (2D table) and/or even a characteristic map (3D table).

According to another aspect of the present invention, the at least one disturbance factor is determined by an input power measurement at the primary charging plate. In one example, the input power measurement can be determined using a calibrated power meter on the primary charging plate. The correction value can be determined from the at least one disturbance factor.

In general, the primary charging plate may have multiple built-in sensors These may already be present in a primary charging plate for various measuring tasks and the built-in sensors may essentially all be used to determine corresponding measurement values. However, the location of the sensors may have been chosen so that they are useful for the operation of the primary charging plate and are technically and/or economically feasible. However, the installation location may not coincide with the location for the measurement of energy to be supplied to a customer. In other words, sensors may be present in the primary charging plate, but may not be installed in such a way that they are located at the location where a measurement of energy to be delivered to a customer should be performed.

Nevertheless, by combining different measurements and/or determining correction values, it may be possible to use existing sensors of a primary charging plate also for billing the amount of energy provided. This additional use may prevent the installation of additional sensors.

According to a further aspect of the present invention, the at least one disturbance factor is determined by a magnetic field measurement in a magnetic field caused by the primary charging plate.

The magnetic field can be considered as a transition point of the amount of energy supplied to a consumer. However, it may be difficult to carry out measurements at this transition point during operation at an economically and technically reasonable cost. The consumers may also contribute to losses through his behavior, for example, by inaccurately positioning their vehicle over a primary charging plate, which losses are his responsibility and not that of the energy supplier providing the charge.

By carrying out a magnetic field measurement during and/or after production in a magnetic field caused by the primary charging plate, it may be possible to determine which share of the energy provided is attributable to the energy supplier and thus to the primary charging plate and which share is attributable to the consumer and thus to the secondary charging plate.

According to yet another aspect of the present invention, a compensation device for determining a correction value for an energy measurement in a primary-side charging plate and for writing the correction value to the primary-side charging plate is provided, which has a selection device, an evaluation device and a writing device.

The selection device is designed to select at least one faulty component and/or component to be corrected in the primary-side charging plate, wherein the at least one faulty component and/or the component to be corrected is influenced by at least one disturbance factor, for example, an error and/or a loss. The disturbance factor may be selected from the group of errors consisting of a measurement error with respect to a comparison value, an intrinsic partial loss and/or intrinsic partial measurement error, an intrinsic loss and/or an intrinsic measurement error, a measurement loss from the secondary charging plate and/or a reaction measurement error from the secondary charging plate.

The type of error in a measurement with built-in sensors can be determined, for example, by comparing it with standardized and/or calibrated high-quality measuring instruments.

The evaluation device is designed to determine an overall disturbance factor of the respective disturbance factors of the at least one faulty and/or to be corrected component. In addition, the evaluation device is designed to determine the correction value from the overall disturbance factor.

The writing device is designed to write the overall disturbance factor as a correction value into a storage unit of the primary-side charging plate. For this purpose, the primary-side storage unit can have an interface via which the compensation device and the primary-side charging plate can exchange data.

In this way, errors that the sensors built into the primary-side charging plate have due to their misuse as energy measurement sensors can be compensated for and the primary-side charging plate can be adapted to provide energy measurement values.

According to another aspect of the present invention, a method for calibrated measurement and/or error-corrected measurement of the energy provided to a secondary-side charging plate in a primary-side charging plate is described. The method provides for determining an input power at the primary-side charging plate and reading out a correction value from a storage unit of the primary-side charging plate, wherein the correction value corrects at least one disturbance factor of at least one faulty component of the primary-side charging plate. The disturbance factor is selected from the group of disturbance factors consisting of a measurement error with respect to a comparison value, an intrinsic partial loss, an intrinsic loss and a reaction measurement loss from the secondary charging plate.

The method further comprises providing a calibrated, an error-corrected and/or a calibrated measurement value.

For example, a charging infrastructure, such as a primary-side charging plate, can be expanded to bill for energy provided by using sensors already used for other purposes.

According to another aspect of the present invention, a primary-side charging plate for calibrated measurement of the energy provided to a secondary-side charging plate is described. The primary-side charging plate has an input power measuring device, a correction device and a storage unit, wherein the input power measuring device is configured to determine an input power at the primary-side charging plate.

The correction device is designed to read a correction value from the storage unit of the primary-side charging plate. The correction value corrects at least one disturbance factor of at least one component of the primary-side charging plate to be corrected. The disturbance factor is selected from the group of disturbance factors consisting of a measurement error with respect to a comparison value, an intrinsic partial loss, an intrinsic loss, a measurement loss from the secondary charging plate, in particular a measurement loss caused by the secondary charging plate, for example by reaction of the secondary coil to the primary coil.

In addition, the correction device is designed to provide a calibrated measurement value and/or an error-corrected measurement value.

The term “error-corrected measurement” or “calibrated measurement” may mean that measurement errors within a specified tolerance limit are balanced or compensated by correction values. The correction values can be determined and saved individually for each primary-side charging plate after the primary-side charging plate has been manufactured, i.e., at the “end of the line”. Furthermore, it is possible that the correction values for a production batch are determined and stored in the devices of this batch. Correction values can also be determined once for the entire production and saved in all devices. The error-corrected measurement value may be very close to the actual amount of energy provided, especially the amount of energy actually transmitted.

A correction value may be determined from a determined overall disturbance factor.

The process of determining the correction values and loading the correction values onto the primary-side charging plate is called calibration. A primary charging plate provided with loaded correction values and the corresponding corrections are carried out is called calibrated.

In contrast to a calibration, a regulatory calibration may, according to the legal definition, only be carried out by regulatory authorities and therefore cannot be carried out by an equipment manufacturer. Calibration essentially concerns the setting of the measuring device by the manufacturer A regulatory calibration, on the other hand, essentially concerns the official confirmation by a regulatory authority that the measuring device complies with the legal requirements.

The measurement and storage of correction values at the end of the production line may therefore be referred to as “calibration” in order to distinguish the official regulatory calibration carried out by the authorities from the process of compensating for disturbance factors at the end of the line.

In other words, end-of-line calibration may ensure that the measurement values obtained by sensors in the inductive energy transfer system agree with regulatory calibrated measurement values within legally permitted tolerance limits.

In one example, the input power measuring device may be a power measuring sensor that is installed in a power input of the primary-side charging plate and performs other functions in addition to power measurement for billing an amount of energy provided.

According to a further aspect of the present invention, a measuring probe for magnetic field measurement is provided, comprising a coil, a coil holding device and a coil positioning device.

The coil holding device is designed to hold the coil in a magnetic field, wherein the coil positioning device is designed to position the coil of the measuring probe above the coil of the primary-side charging plate in such a way that they experience the greatest possible coupling to one another and in particular the maximum achievable coupling.

The measuring probe may make it possible to carry out standardized comparative measurements under the same conditions for the consumer, i.e., for the secondary-side charging plate. The coil positioning device can ensure that the coil is arranged at essentially the same position for maximum coupling during each comparison measurement of different primary-side charging plates. Thus, standard ambient conditions may be created when determining correction values and when calibrating a primary-side charging plate.

According to a further aspect of the present invention, the coil positioning device further comprises a locking element, wherein the locking element is adapted to lock into the housing of a primary-side charging plate in order to bring about a large or strong coupling with the primary-side coil. The locking element may essentially ensure a defined positioning in order to achieve the highest possible coupling. The highest possible coupling is achieved if the greatest possible magnetic coupling factor can be determined between the primary-side charging plate and the secondary-side charging plate.

The locking element can determine the alignment of the measuring probe with the coil relative to the primary-side charging plate.

According to another aspect of the present invention, the coil holding device is designed as a table.

The table shape allows an essentially parallel alignment of the measuring probe coil to the primary-side charging plate and in particular to a primary coil built into the primary-side charging plate.

According to yet another aspect of the present invention, a computer-readable storage medium is provided, on which a program code is stored which, when it is executed by a processor, executes at least one of the methods.

A floppy disk, a hard disk, a USB (Universal Serial Bus) storage unit, a RAM (Random Access Memory), a ROM (Read Only Memory), or an EPROM (Erasable Programmable Read Only Memory) may be used as a computer-readable storage medium. An ASIC (application-specific integrated circuit) or an FPGA (field-programmable gate array) as well as an SSD (solid-state drive) technology or a flash-based storage medium can also be used as a storage medium.

According to yet another aspect of the present invention, a program element is provided which, when executed by a processor, performs at least one of the methods.

### BRIEF DESCRIPTION OF THE DRAWINGS

Further example embodiments of the present invention are described hereinafter with reference to the figures.

FIG. 1 shows an inductive charging system according to an example embodiment of the present invention.

FIG. 2 shows a perspective rear view of a measuring probe for a magnetic field measurement according to an example embodiment of the present invention.

FIG. 3 shows a perspective front view of a measuring probe for a magnetic field measurement according to an example embodiment of the present invention.

FIG. 4 shows a further perspective front view of a measuring probe for a magnetic field measurement according to an example embodiment of the present invention.

FIG. 5 shows a detailed view from the perspective front view of FIG. 3 of a measuring probe for a magnetic field measurement according to an example embodiment of the present invention.

FIG. 6 shows a schematic block diagram of the losses occurring on the primary and secondary-sides of an inductive charging system according to an example embodiment of the present invention.

FIG. 7 shows an arrangement for calibrating the input power measurement of a GA according to an example embodiment of the present invention.

FIG. 8 shows an arrangement for calibrating the losses of the GA without the PFC filter according to an example embodiment of the present invention.

FIG. 9 shows an arrangement for calibrating the intrinsic losses of the GA according to an example embodiment of the present invention.

FIG. 10 shows an arrangement for complete calibration of a power measurement in a GA according to an example embodiment of the present invention.

FIG. 11 shows a flow chart for methods for determining a measurement error in a primary-side charging plate when providing energy to a secondary charging plate according to an example embodiment of the present invention.

FIG. 12 shows a flowchart of methods for error-corrected measuring of the energy provided for a secondary-side charging plate in a primary-side charging plate according to an example embodiment of the present invention.

### DETAILED DESCRIPTION

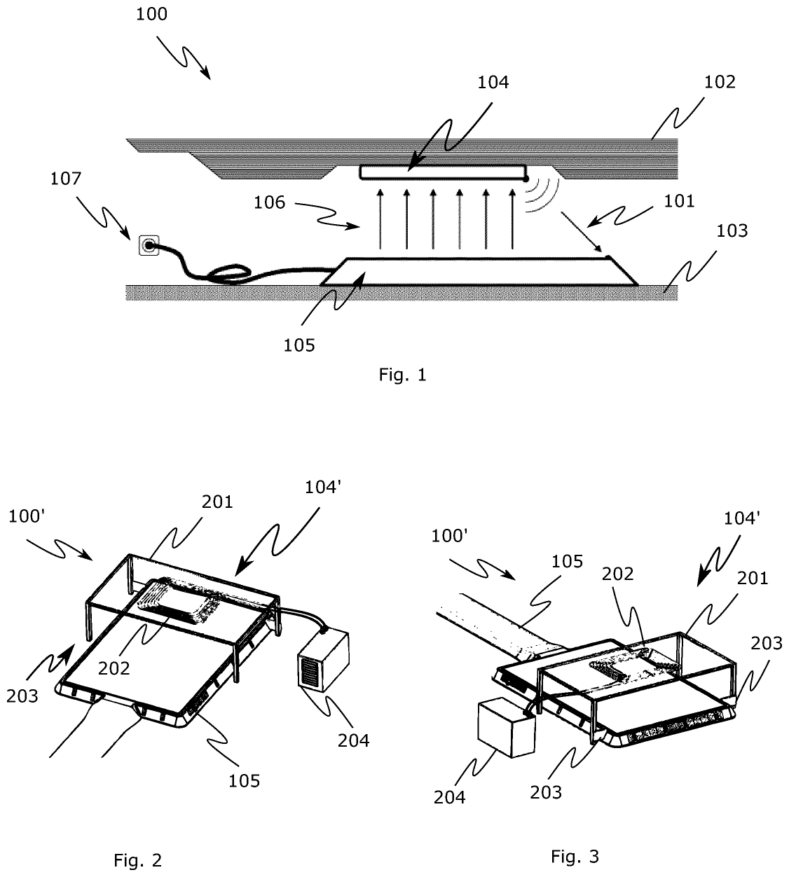

The illustrations in the figures are schematic and not to scale. In the following description of FIG. 1 to FIG. 12, the same reference numbers are used for the same or corresponding elements.

In this text, the terms “capacitor” and “capacitance” as well as “coil” or “choke” and “inductance” may be used synonymously and should not be interpreted restrictively unless otherwise specified. Furthermore, the terms “energy” and “power” may be used interchangeably and, unless otherwise specified, should not be interpreted restrictively. A power can be converted by calculation into an energy and vice versa.

FIG. 1 shows an inductive charging system 100 or system 100 for energy transfer according to an example embodiment of the present invention. This shows a side view of a system for contactless charging of an electric vehicle. Below a vehicle chassis 102 there is a Vehicle Assembly (VA) 104 or a Car Pad Module (CPM) 104, which serves to supply the vehicle 102 with power. A magnetic field 106 is used to transmit the energy, which is inductively provided by a Ground Assembly (GA) 105 or a Ground Pad Module (GPM) 105 fixedly mounted on a floor 103. The energy required for charging is taken from the main connection 107, which can be either alternating current (AC) or direct current (DC). For communication between VA 104 and GA 105, a separate connection 101 is used, which can use, for example, a radio protocol such as WLAN (Wireless LAN), UWB (Ultra-Wideband) or NFC. This connection can be used as a feedback channel 101 or as a communication channel 101 through which VA 104 and GA 105 can exchange information. Both the magnetic field for energy transmission 106 and the radio signal 101 are electromagnetic waves, but they have different frequencies.

FIG. 2 shows a perspective rear view of a measuring probe 104′ for a magnetic field measurement according to an example embodiment of the present invention.

The measuring probe 104′ or MVA 104′ is arranged above the GA 105 and is table-shaped. The measuring probe 104′ has a coil 202 and a coil holding device 201. The coil holding device 201 is table-shaped and has a coil positioning device 203 on the table legs.

The coil holding device 201 is designed to hold the coil 202 in a magnetic field of the GA 105, wherein the coil positioning device 203 is designed to position the coil 202 in such a way that the coil of the measuring probe together with the coil of the primary-side charging plate experiences the greatest possible coupling and, in particular, the maximum achievable coupling.

Even if the coil of the measuring probe is essentially aligned purely geometrically in relation to the coil of the primary-side charging plate in such a way that the greatest possible coupling is achieved between the two coils, the coupling essentially only occurs at the moment the magnetic field is switched on.

The coil is connected to a measuring device box 204 or load 204 in which the energy is stored or dissipated. Similarly, at the connection point where the load 204 is connected to the coil, calibrated measuring devices for performing a power and/or energy measurement are also connected. In particular, comparative measurements can be carried out using calibrated measuring instruments. The compensation device 706 can be connected to the measuring device box 204 and/or to the connection point between the coil and the measuring device box (the compensation device 706 is not shown in FIG. 2).

The measuring probe 104′ is used as a standardized secondary-side measuring system 104′, which essentially replicates the functionality of the VA 104 under essentially standardized conditions.

FIG. 3 shows a perspective front view of a measuring probe 104′ for a magnetic field measurement according to an example embodiment of the present invention.

In this view, the locking elements 203 can be seen, which essentially ensure that the coil 202 is positioned the same way in relation to the GA 105 for each measurement.

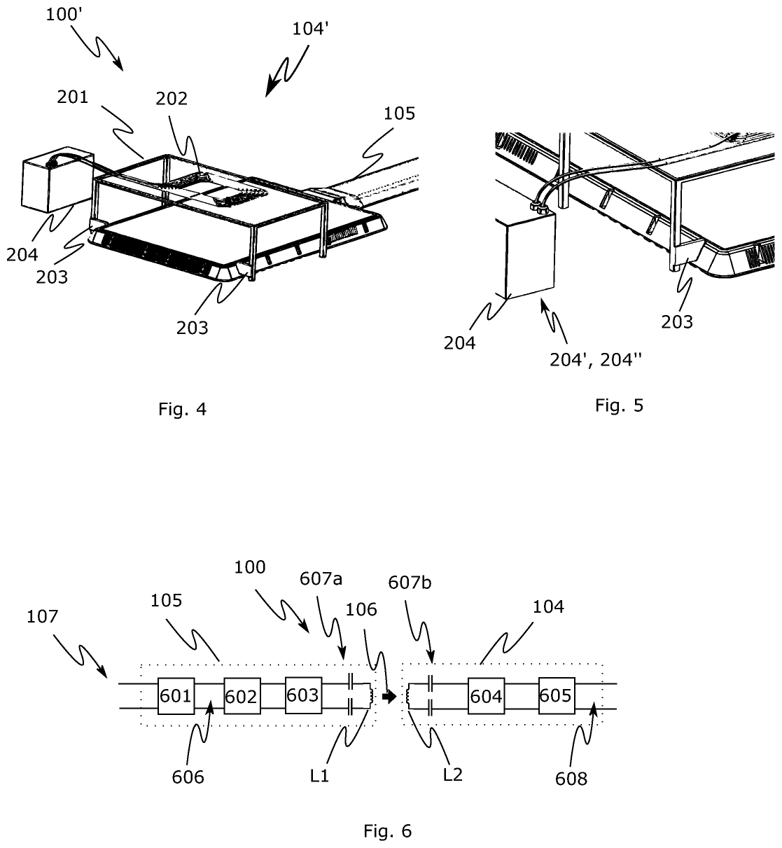

FIG. 4 shows a further perspective front view of a measuring probe 104′ for a magnetic field measurement according to an example embodiment of the present invention.

FIG. 5 shows a detailed view from the perspective front view of FIG. 3 of a measuring probe 104′ for a magnetic field measurement according to an example embodiment of the present invention.

Here it can be seen how the locking element 203 is physically connected to the GA 105, for example, by locking, in order to establish a constant position of the coil 202 relative to the GA 105 when multiple Gas 105 are to be calibrated one after the other. The locking element 203 is at least partially adapted to the contour of the DA 105, in particular, to the shape of a housing of a GA 105.

As can be seen from FIGS. 2 to 5, a basic measurement setup for calibrating an inductive charging system 100′ has the primary-side charging plate 105 or GA 105, which is provided at the end of a continuous production process. The measurement setup also includes the measuring probe 104′ or the secondary-side measuring system 104′ (Measurement Vehicle Assembly, MVA), which is used instead of a VA 104. The MVA 104′ thus represents the secondary-side charging plate 104 (Vehicle Assembly, VA), which would be installed on the electric vehicle during operation.

The measuring probe 104′ can ensure consistent and/or standardized measuring conditions during a regulatory or normal calibration, whereas vehicle-specific VAs 104 would essentially always produce different measuring results The different results can arise, for example, from the fact that the primary-side coil has a different geometric alignment to the VA coil, due to different designs of the coils, or due to different shielding or variances in the positioning relative to the primary-side charging plate.

The MVA 104′ is designed in such a way that it measures the power transmitted by the GA 105 essentially without any reaction. The MVA 104′ is realized as a coil holding device 201, in particular as a Plexiglas table 201, with embedded coil 202 and connected load 204′ (not shown in FIGS. 2 to 5). The load 204′ is adaptable and can be housed, for example, in the measuring box 204. The load 204′ has connections for the measurement of current and voltage by calibrated and/or standardized measuring devices 204″ (not shown in FIGS. 2 to 5).

The coil positioning device 203 of the MVA 104′ is configured to position the coil 202 in a magnetic field generated by the GA 105 such that the coil 202 experiences maximum coupling with the magnetic field. The MVA 104′ locks into the position of maximum possible magnetic coupling above the GA 105. In other words, on the one hand the height of the coil holding device 201 and on the other hand the alignment to a center position of the GA 105 are selected such that the magnetic field penetrating the coil 202 experiences a substantially maximum magnetic coupling with the coil 202. The locking elements 203, which determine a distance between the coil holding device 201 and the GA 105, can be used to align the center position and/or for horizontal alignment.

The power provided to the MVA 104′ via the magnetic field 106 from the GA 105 is measured with the calibrated power measuring devices 204′.

Power losses and/or energy losses within the MVA 104′ are measured, for example, as calorimetric heat and deducted from the measurement value of the calibrated measuring devices 204″. The determination of losses via calorimetric heat is only one example of loss determination, in particular, the determination of disturbance factors. Since the resistance of the coil is known, the power losses at the MVA can alternatively be calculated.

Thus, essentially all losses caused by the secondary-side are excluded by this measuring arrangement Power losses of the MVA can be measured at the end of the band. However, this requires a complex procedure. In an example, the power loss of the MVA may essentially just be calculated and then added as a constant to the measured power.

Due to the design, the transfer point and the point of measurement of the power are not identical. While the power is measured at the input of the primary coil, the point at which the power is transferred to the consumer is the magnetic field. However, since the losses and/or disturbance factors between the measuring point and the transfer point are determined and corrected using this method, the transmitted power at the transfer point can be determined, i.e., the transmitted power in the magnetic field.

At the MVA 104′, the calibrated measuring devices 204″ can thus be used to carry out an essentially precise measurement of the power transmitted by the GA, which corresponds to a measurement directly in the alternating magnetic field 106.

The calibration of each GA 105 is carried out at the end of the production process, for example, in quality assurance. Calibration is therefore essentially the last step in the production process, i.e., the so-called “line decalibration”.

While the measurements are being performed, the GA is switched to a test mode, which switches off the diagnostic functions implemented in the GA 105 for functional safety during the calibration period. This test mode can be switched on and off by a compensation device 708.

The load 204′ at the output of the MVA 104′ is adjusted so that the nominal power range at the MVA is covered for calibration. For example, a nominal power range can cover a range from 9.1 kW to 11.1 kW. In other words, during calibration, deviations of the measurement values generated by the GA 105 under consideration from standardized measurement values are determined in order to be able to use these deviations determined under ideal conditions for correction during operation of the GA 105.

During the measurements carried out during the calibration phase, the input voltage on the GA 105 and the ambient temperature are kept constant. The input voltage can be kept constant by a regulated power supply. It may be assumed that the temperature remains constant during the measurement process. By keeping the input voltage at the main connection 107 constant, the input current essentially changes when the power changes and the input acts as a constant voltage source.

One aim of the regulatory calibration measurements and/or calibration measurements may be to determine a correction curve, which is then stored in the GA 105. The correction curve is used to correct the measured power so that it corresponds to the calibrated power measurement at the MVA 104′. In other words, after applying the correction curve in real operation, the power and/or energy provided by the GA 105 may not differ from those of the reference of the measuring probe 104′. For this purpose, for example, a display on the correction device 705′ can be compared with the display of the measuring devices 204″. A GA 105 calibrated and/or verified in this way, i.e., a GA to which a correction curve is applied, can be sealed and marked in accordance with the MessEV ordinance. It is then ready for regulatory calibration-compliant operation without any further external intervention and can be used, among other things, for the public and legally compliant sale of energy.

The MVA 104′ can also be used by regulatory calibration offices to check the inductive charging system 100, in particular, to check the GA 105 at the installation site. The inspection can be carried out on site without damaging the seal of the GA 105 or opening the GA 105, which means that the GA 105 may fulfil another requirement of the calibration law. During the control measurement it is determined that the power and/or energy measured by the GA 105 is within the tolerance limit for measurement errors prescribed by the calibration law. For this purpose, for example, a display on the correction device 705′ can be compared with the display of the measuring devices 204″.

The MID Directive sets out specific requirements in Annex V specifically for the regulatory calibration of electricity meters. In Germany, for example, charging stations are assigned to meter class A and must not exceed a measurement error of ±3.5% in the normal temperature range. The requirements were mainly formulated for energy consumption measurement at the handover point of wired electricity networks. The transfer point or transition point is the interface between the energy supplier and the energy consumer, at which the energy consumed is measured as a cost for the energy consumer, for example, the meter in the electricity cabinet of a house.

However, when inductively charging electric vehicles, there is no cable to which an energy meter can be attached at the handover point. In contrast, the transfer takes place in the magnetic field 106 in the air gap between the primary charging coil L1 and the secondary charging coil L2 or GA 105 and VA 104. However, cost-effective measurement of the transmitted energy cannot be carried out in the magnetic field. To comply with calibration law, measurements are taken at another location and the value in the magnetic field is calculated.

The error-corrected measurement as proposed by the subject matter of the present invention helps to realize a technically and economically feasible and also legally sustainable recording of the energy consumed.

Because the measurement is not carried out directly in the magnetic field, but by sensors in the GA 105, which are adapted accordingly by calibration, a reliable result can be obtained within defined error tolerance limits and a direct measurement of the transmitted energy in a high-frequency and alternating magnetic field at 85 kHz, with an active power of 11 kW and with an apparent power of over 100 kVA can be avoided. A measurement in such a strong magnetic field with the accuracy, reproducibility and reliability required for consumption measurement would be too complex. By measuring within the GA 105, the use of complex laboratory measuring technology and laborious measurements under laboratory conditions can be avoided.

The proposed primary-side charging plate 105 for error-corrected measurement makes it possible to dispense with a complex measuring system with which no economical energy measurement can be carried out directly on the magnetic field. Since the use of existing components makes use of a measuring sensor system 702, 703 already integrated in the primary-side charging plate 105, the integration of expensive precision measuring technology and/or laboratory measuring technology into an inductive charging station, which is complex in terms of cost and size, is avoided by means of the proposed primary-side charging plate. Consequently, the proposed primary-side charging plate 105 can be used to create an energy distribution system for inductive charging that is economically and structurally feasible for a charging station operator.

By using coupled coils, the secondary-side and the way in which it is embedded in the vehicle, as well as the behavior of the consumer, have a significant influence on the consumption losses of the primary-side 105. The invention makes it possible to carry out a calibrated energy measurement using an MVA, which is unaffected by losses that can be caused by a consumer. The difference between the output energy and the input energy is therefore the energy loss in the inductive charging system, which was only caused by the primary-side, and therefore should not be charged to the consumer and must therefore be deducted from the energy measurement. Thus, the proposed solution may also meet the requirements of the calibration law in an inductive charging system.

Energy losses in the magnetic field 106 in active operation depend essentially on the accuracy of the parking position and on the vehicle height relative to the GA 105, e.g., as influenced by the load of the vehicle. These factors are essentially influenced by the consumer. If the positioning is inaccurate, i.e., if there is an offset between the primary coil L1 and the secondary coil L2, or if the vehicle is at a higher height, the losses increase. By simultaneously reducing the magnetic coupling and controlling the increase in energy transfer on the primary side, which tries to compensate for these losses, the losses in the power electronics on the primary side increase. Further influences on the losses on the primary side are the battery charge level of the electric vehicle, the charging power required by the vehicle, the size and shielding as well as the metallic environment of the secondary coil and the power electronics installed there.

These are factors influencing the energy losses on the primary side 105, which originate from the vehicle and the driver and therefore, according to the calibration rules, must also be attributed to the driver and borne by him. By avoiding consumption measurement directly at the magnetic field, the wrongful allocation of these losses to the energy supplier is also avoided.

FIG. 6 shows a schematic block diagram of the losses occurring on the primary 105 and secondary 104 sides of an inductive charging system according to an example embodiment of the present invention.

The causes of the losses are shown in FIG. 6. The main causes of losses are three component groups 601, 602, 603 on the primary side 105 and the magnetic field 106 itself. In these three component groups 601, 602, 603 and in the magnetic field 106, disturbance factors arise, such as losses, which are influenced by the consumer side. These losses should be charged to the consumer and not to the energy supplier.

The amount of energy provided by the GA 105 to the VA 104 is supplied via the mains connection 107. It passes through a PFC (Power Factor Correction) filter 601, which ensures that the alternating current (AC) provided via the mains connection 107 behaves as much as possible like a resistive resistor or ohmic resistor and contains the lowest possible reactive power components.

After the PFC filter 601, the energy is supplied to a HVDC (High Voltage Direct Current) circuit 606 and reaches the inverter 602. This generates an alternating voltage of 85 kHz, i.e., with the frequency of the magnetic field 106 to be generated from the alternating voltage with the mains frequency, for example, 50 Hz or 60 Hz. However, before the energy is fed into the primary coil L1, an impedance matching takes place in the primary-side impedance matching network 603

The energy is passed on to the primary coil L1 via primary circuit capacitors 607a, which generates the magnetic field 106.

The magnetic field 106 passes through the secondary coil L2 and thus the energy reaches the secondary-side. From the secondary coil L2, the energy is passed on to the secondary impedance matching network 604 via the secondary capacitors 607b. From there, the energy is passed on via the rectifier 605 to the secondary-side HVDC circuit, in which the vehicle battery (not shown in FIG. 6) is then charged.

Power losses occur in the individual components of the GA and VA. The causes of power losses in the individual components can be determined by the driver or consumer, the vehicle type and thus also by the consumer and the energy supplier.

In the PFC Filter 601, −2% to −5% power loss can occur. This power loss is influenced by the driver or consumer, as the driver determines the parking position, load and battery charge level. The vehicle type has an influence on the loss that occurs in this component due to the charging power required by the vehicle type and the vehicle type itself, for example, how the vehicle is constructed, what shape it has and what materials are used. The energy supplier, for example, the energy utility, influences the power loss in this component 601 by selecting the design of the GA 105. The PFC Filter 601 is an electronic circuit which consists of components and their connection on the PCB (Printed Circuit Board). Components and connecting lines have losses. Depending on their choice and design, i.e., the design of the GA 105, these losses can be greater or smaller. There are also parasitic resistances, inductances and capacitances, which also lead to losses. This may apply to all components of power electronics.

The converter 602 can experience power losses of −1.5% to −7%. This power loss is influenced by the driver or consumer, as the driver determines the parking position or load. The type of vehicle has an influence on the loss that occurs in this component, for example, through the type of vehicle, its shape and the materials used. The energy supplier, for example, the energy utility, influences the power loss in this component 602 by selecting the design of the GA 105.

In the primary-side impedance matching network 603, −0.5% to −4% power loss can occur. This power loss is influenced by the driver or consumer, as the driver determines the parking position, load, battery charge level and the selected charging power. The charging power is requested by the vehicle. This usually depends on the charge of the battery. If the battery is empty, the entire power is often required, i.e., 100% power. When the battery is almost full, the power is usually gradually reduced to lower values. The type of vehicle also has an influence on the power loss that occurs in this component, for example, through the type of vehicle, its shape and the materials used. The energy supplier, for example the energy utility, influences the power loss in this component 603 by selecting the design of the GA 105.

In the magnetic field 106, −1.5% to −7% power loss can occur. This power loss is influenced by the driver or consumer, as the driver determines the parking position and load. The vehicle type has an influence on the power loss arising in the magnetic field 106 due to the vehicle type itself, for example, how the vehicle is constructed, what shape it has and what materials are used, as well as the size of the secondary coil L2 installed in the vehicle type. Likewise, the VA design chosen by the vehicle manufacturer for the vehicle type, which may also be related to the coil size and/or the material used, can have an influence on the magnetic field and its losses or disturbance factors. Since the driver usually selects the vehicle type, he is also responsible for the power losses incurred by the vehicle. The energy supplier, for example, the energy utility, influences the power loss in the magnetic field 106 by selecting the design of the GA 105.

In the secondary-side impedance matching network 604, −0.5% to −4% power loss can occur. This power loss is influenced by the driver or consumer, through the parking position, load and battery charge level. The vehicle type has an influence on the power loss occurring in this component due to the charging power required by the vehicle type.

In the rectifier 605, −1% to −3% power loss can occur. This power loss is influenced by the driver or consumer, through the battery charge level.

The knowledge of the power losses and the loss causes in GA and VA enables the method for determining a measurement error and the compensation device for determining a measurement error to select the at least one faulty component in the primary-side charging plate 105. In combination with the method for error-corrected measurement of the energy provided for a secondary-side charging plate 104 in a primary-side charging plate 105, it may be possible to implement a method that complies with calibration law for measuring the energy transmitted by an inductive charging system 100 with a cause-based allocation of the losses occurring therein. Here, the results of the method for determining a measurement error are used in the method for error-corrected measurement. The exchange of information may be carried out by writing and/or reading a correction value into/from a storage unit of the primary-side charging plate 105.

It may be considered as an aspect of the present invention to carry out a differential measurement at at least two measuring points of the energy transmission path using calibrated measuring systems and a substantially ideal measuring coil 202 instead of measuring at a transfer point in an inductive charging system in order to determine and compensate for the consumer-side losses from the differential measurement.

The term “ideal measuring coil 202” may refer to the fact that the coil 202, in particular, the measuring probe 104′, under essentially ideal conditions at the end of the manufacturing process but still in the manufacturing plant, can be positioned in the magnetic field 106 of a GA 105 such that the coil 202 experiences a large coupling with the magnetic field 106.

With the measuring method according to the invention, a measuring error of less than ±3.5% may be achieved. In this case, requirements of calibration law and technical feasibility may be taken into account. The measuring method according to the invention may be suitable for calibrating an inductive charging system 100 during production and for checking the calibration on site during later operation, for example by a calibration authority.

The consideration of the power losses occurring in the individual components and the causes of the losses shows that power losses related to the energy supplier and the GA design 105 occur in the PFC filter 601, the converter 602, the primary-side impedance matching network 603 and the magnetic field 106. The GA 105 is the responsibility of the energy supplier as operator of the GA. However, it has also been shown that these components 601, 602, 603, 106 are influenced by the consumer and recipient of the energy, for example, by the parking position, the load, the battery condition and the charging power.

Thus, according to one aspect of the present invention, a method for calibrated measurement of the energy provided for a secondary-side charging plate 104 in a primary-side charging plate and/or a primary-side charging plate 105 for measuring the energy provided for a secondary-side charging plate 104 is provided, in which energy losses have been taken into account in a cause-related manner. Energy losses caused by the primary-side charging plate are not included in the measurement result. Thus, the measurement result contains only the energy supplied to the load for charging, including the energy losses generated by the secondary-side charging plate 104 and the behavior of the load.

The exclusion of energy losses on the primary side charging plate, which are essentially the responsibility of the energy supplier, and the inclusion of disturbance factors influenced by the consumer and recipient of the energy, such as energy losses, for example, due to the parking position, the load, the battery condition and the charging power, can be regarded as a cause-related measurement. Thus, the measurement value for the energy supplied is suitable for billing the consumer.

In order to avoid the use of complex technology such as laboratory measurement technology in such a selective direct measurement during operation, i.e., essentially during charging of a vehicle, a two-stage procedure is proposed in which a correction value is first determined during a calibration phase under essentially ideal conditions, which essentially only includes the losses of the primary-side charging plate and is not influenced by the driver. This correction value is stored in the GA 105.

During an operating phase, the energy actually provided by the energy supplier can then be determined essentially solely by the GA 105 and the sensors installed in it by an input power measurement and deduction of the correction value. This is the energy delivered to the consumer, which can also be billed to the consumer. The energy supplied by the energy supplier shall include the energy supplied to the consumer, including losses which, in the GA 105, are caused by the consumer and are therefore outside the control of the energy supplier.

The losses caused by the GA 105 will not be charged to the consumer.

Such a determination of the energy provided should be in accordance with calibration law.

The calibration of the measurement of magnetically transmitted energy is carried out during the production of the system, in particular, at the end of the line and not during the active operation of the system. The calibration of the measurement of magnetically transmitted energy is performed by measuring the power at two different locations in the system 100. This involves measuring the input power on the primary side and measuring the magnetic power in an idealized measuring coil 104′ on the secondary side, whereby the idealized measuring coil 104′ simulates a VA 104.

Providing the two measurements makes it possible to form a difference. For the measurement of the power in accordance with calibration law, the power is measured in a first measurement directly at the input of the primary side 105 using calibrated measuring sensors. This measurement is carried out using a calibrated measuring device. The two measurements are used for calibration before the system is put into operation in order to ensure that the measurement during the operating phase complies with calibration law.

By comparing the measurement of the measuring sensors with calibrated measuring devices, a possible measurement error of the measuring sensors can be compensated by calibration. The error of the measured power at the input of the primary side 105 is referred to as P_{GA,err} and expresses the measurement error of the measuring sensors 702 at the input of the GA 105

In addition to the measurement and calibration of the input measuring sensors 702, in a second measurement the intrinsic power loss of the primary side 105 is determined as a disturbance factor, which is free from the influencing factors of the secondary side 104 and is therefore also attributable to the energy supplier, since it depends on the intrinsic factors of the GA 105 such as the GA design. This intrinsic power loss of the primary side 105 is determined as part of the correction value and is deducted from the power measurement of the input measuring sensors in the subsequent measurements during operation of the GA 105. The intrinsic power loss of the primary side determined with the second measurement using the idealized measuring probe MVA 104′ is referred to as Pᵢₙₜᵣ and must be deducted from the power measurement since it is caused by the GA 105 used by the energy supplier and therefore cannot be billed to the consumer.

In addition, during the calibration phase, a correction value of the power loss P_{MVA,err} of the measuring coil on the secondary side 104, 104′ is determined, which is added to the input power measurement during operation. This disturbance factor is the power loss of the ideal measuring probe.

Losses on the secondary side are essentially always attributed to the consumer.

When the input power P(i) is measured at the input of the primary side at time i*Δt with the input power measurement sensors installed in the GA 105 during operation of the GA 105, the value of the input power measurement P(i) must be compensated with three correction factors P_{GA,err}, Pᵢₙₜᵣ, P_{MVA,err} in order to arrive at a calibrated power measurement provided to the consumer. The calibrated power P_{cal}(i) at time i*Δt is:

$${P}_{cal} ( i ) = P ( i ) - {P}_{GA , err} - {P}_{intr} + {P}_{MVA , err}$$

The calibrated power P_{cal}(i) at time i*Δt is thus the measured power P(i) at the input of the primary-side 105 at time i*Δt minus the error and/or disturbance factor of the measured power at the input of the primary side P_{GA,err}, minus the disturbance factor of the intrinsic power loss Pᵢₙₜᵣ of the primary side and plus the disturbance factor of the power loss P_{MVA,err} of the measuring coil MVA 104′ on the secondary side. Here, i is an integer value that indicates the index of the input power measurement of the GA 105. Δt is the time interval between the measurements.

The value P_{cal}(i) can be displayed on a display device of the correction device 705′ as the power currently delivered to the vehicle.

The correction factors resulting from the disturbance factors depend on the instantaneous power, namely P_{GA,err}=P_{GA,err}(P(i)), Pᵢₙₜᵣ=Pᵢₙₜᵣ(P(i)) and P_{MVA,err}=P_{MVA,err}(P(i)). This takes into account that the power loss can depend on the current and thus describes a characteristic curve. Such a characteristic curve may be written into the storage unit 705 of the primary-side charging plate 105 for correction. In another example, the power dissipation may be a constant and essentially independent of the current.

The energy W_{cal} provided to the consumer is calculated from the calibrated power measurement P_{cal}(i) by multiplying the power by the overall time of the measurement. When the energy flow changes, the energy is calculated from the integration of the power over time, which is approximated by discrete measurements as the sum of all power measurements multiplied by the measurement interval time.

$${W}_{cal} = {\int }_{0}^{T} {P}_{cal} ( t ) dt \approx {\sum }_{i = 1}^{i = N} {P}_{cal} ( i ) * Δ t$$

Here T denotes the overall time of the measurement, dt the differential of the time and N the overall number of measurements.

During the calibration phase of the power measurement, compensation values and/or a compensation characteristic curve are determined for the measurement phase. To determine the compensation characteristic or correction curve, a defined nominal power range is run through on the MVA 104′, for example, a power range from 9.1 kW to 11.1 kW.

The characteristic curves of the power correction parameters P_{GA,err} and Pᵢₙₜᵣ, in particular, the characteristics of the corresponding correction values, can be implemented either as a first-order polynomial or as conversion tables in software and written into the storage unit 705. In this case, a current dependency of P_{MVA,err} can be neglected and included as a constant in the calculation.

The polynomial has the form:

$${P}_{corr} ( i ) = a * P ( i ) + b$$

A translation table is stored in the following form.

$${P}_{corr} ( i ) = \{ {P}_{corr , 1} , {P}_{corr , 2} , … {P}_{corr , M} \}$$

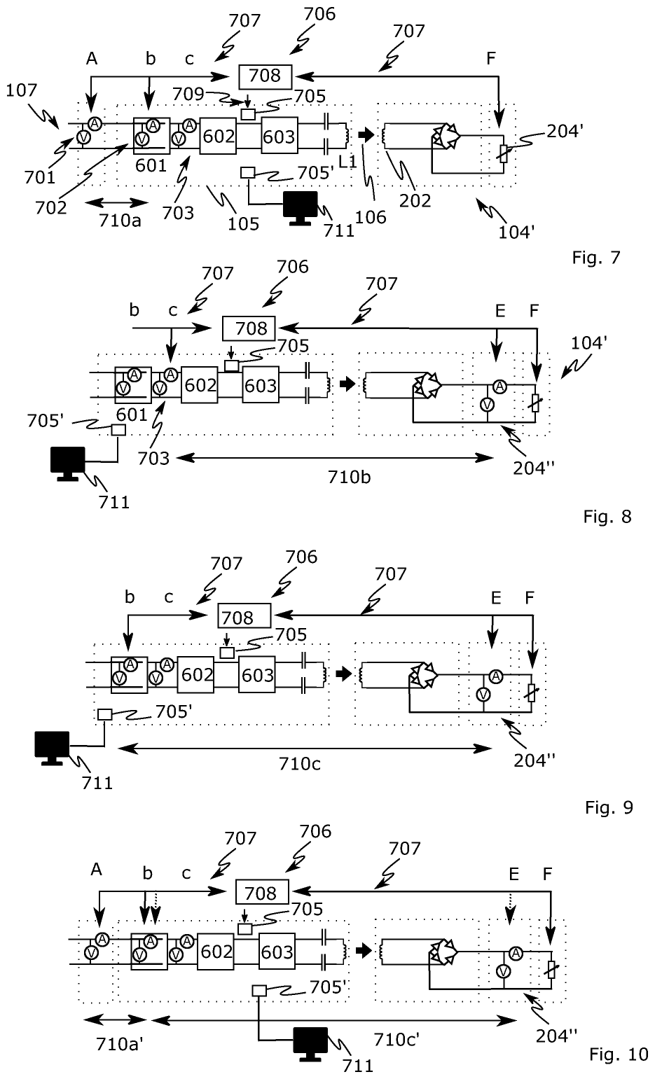

FIGS. 7 to 10 show different methods for calibrating the power measurement. These are different embodiments of methods that can be used to approximate the output power. The methods may be implemented in a compensation device 706. A switch may be provided in the compensation device 706 with which at least one of the methods can be selected.

FIG. 7 shows an arrangement for calibrating the input power measurement of a GA 105 according to an example embodiment of the present invention.

FIG. 7 shows the compensation device 706 for determining a correction value and for writing or loading a primary-side charging plate 105 with the correction value. The compensation device 706 thus serves to calibrate a primary-side charging plate 105 and has a selection device 707, an evaluation device 708 and a writing device 709.

The selection device 707 is designed to select at least one component 601, 602, 603 to be corrected or a faulty component 601, 602, 603 in the primary-side charging plate 105 and/or to select at least one comparison measuring device 701, 204″, for example, a calibrated sensor 701, 204″ and/or calibrated sensor 701, 204″. The component 601, 602, 603 to be corrected may be selected indirectly by selecting corresponding sensors 702, 703 installed in the primary-side charging plate 105 and its disturbance factor, for example, its errors or losses, may be determined by a differential measurement via the sensors 701, 702, 703, 204″.

The at least one component 601, 602, 603 to be corrected is influenced by at least one disturbance factor selected from the group of disturbance factors consisting of a measurement error P_{GA,err}, with respect to a comparison value, an intrinsic power loss Pᵢₙₜᵣ or an intrinsic loss Pᵢₙₜᵣ, and a loss P_{MVA,err}, in particular, a measurement loss P_{MVA,err}, from the secondary charging plate 104, 104′.

The evaluation device 708 is further designed to determine an overall disturbance factor of the respective disturbance factors, for example, the power losses P_{GA,err}, Pᵢₙₜᵣ, P_{MVA,err}, of the at least one faulty component 601, 602, 603 and to determine a correction value from the overall disturbance factor of the respective losses of the at least one component.

The evaluation device is designed to determine a correction value from the overall disturbance factor and to write the overall disturbance factor as a correction value into a storage unit 705 of the primary-side charging plate 105 by a writing device 709.

In FIG. 7 to FIG. 10, the selection of calibrated comparison sensors is indicated by capital letters A, E, F and the selection of sensors installed in the primary-side charging plate 105 is indicated by small letters b, c.

The primary-side charging plate 105 or GA 105 can be used for calibrated measurement of the energy provided to a secondary-side charging plate 104, 104′. The energy is provided via the magnetic field 106.

The primary-side charging plate 105 has an input power measuring device 702, a storage unit 705 and a correction device 705′, wherein the input power measuring device 702 or installed sensor 702 is configured to determine an input power P(i) at the primary-side charging plate 105.

The correction device 705′ is configured to read a correction value from the storage unit 705 of the primary-side charging plate 105. The correction value corrects at least one disturbance factor, for example, an error, a loss or a power loss, of at least one loss-affected component 601, 602, 603 of the primary-side charging plate or of at least one component 601, 602, 603 of the primary-side charging plate to be corrected, wherein the disturbance factor is selected from the group of power losses consisting of a loss measurement error P_{GA,err}, with respect to a calibrated comparison sensor value, an intrinsic loss Pᵢₙₜᵣ and a measurement loss P_{MVA,err} from the secondary charging plate.

In an example, a correction value may be the negatively signed value of a disturbance factor, such as a loss P_{GA,err}, Pᵢₙₜᵣ, P_{MVA,err}.

The correction device 705′ is configured to provide a corrected measurement value. The actual power consumption value P_{cal}(i) assigned to the consumer can then be displayed on a display device 711 connected to the correction device 705′. In an example, the energy consumption required by MID/MessEG is displayed, for example, in kWh. The power can optionally be displayed for information purposes.

To measure the input power, the input sensors 702 installed in the GA 105 or the input power measuring device 702 are used, for example, a voltage sensor and a current sensor. At the end of the line, i.e., at the end of the production process, the measurement of the input power by the sensors 702 of the GA 105 is compared with a calibrated power meter 701. The measurement is carried out over the nominal power range, for example, a power range from 9.1 kW to 11.1 kW. In order to cover the power range, a variable load 704 is used on the MVA 104′, which is controlled, for example, by the selection device 707. The control of the comparison measurement is shown with letter F in FIG. 7.

The comparison between the power measured by the installed sensors 702 and the calibrated measuring device 701 thus results in the disturbance factor or the correction power parameter P_{GA,err} as a characteristic curve depending on the input power, with which the sensor values of the input power measuring device 702 are corrected for a certain current power absorption.

The correction measurement is therefore carried out in the calibration range 710a for the determination of P_{GA,err} between the calibrated sensors 701 and the input sensors 702. For this purpose, the setting A, b, F is selected on the selection device 707.

If the correction values are stored in the storage unit 705, the GA 105 can independently correct its sensor values of the input sensors 702 in an autonomous operation. The corrected sensors thus provide a calibrated input power measurement.

$${P}_{cal} ( i ) = P ( i ) - {P}_{GA , err}$$

FIG. 8 shows an arrangement for calibrating the losses of the GA 105 without the PFC filter 601 according to an example embodiment of the present invention.

The calibration of the losses of the GA 105 without the PFC filter 601 serves to determine a part P′ᵢₙₜᵣ of the intrinsic losses of the GA 105. To determine this, the internal power measurement in the direction of power propagation behind the PFC filter 601 is compared with the measured power at the MVA 104′ at the end of the line. The internal power measurement behind the PFC filter 601 is carried out with the sensors 703 built into the GA 105, which are arranged in the direction of power propagation behind the PFC filter 601.

The measurement is carried out over the nominal power range, which can be varied with the variable load 204′ of the MVA 104′. The power losses P_{MVA,err} of the MVA 104′ are deducted. The comparison between the power measured by the installed sensors 703 with the calibrated sensors 204″ of the MVA 104′ thus results in a correction parameter or correction value for the intrinsic power loss P′ᵢₙₜᵣ as a characteristic curve depending on the input power, with which the sensor values of the sensors 703 behind the PFC filter must be corrected during the autonomous operation of the GA 105 in order to be able to provide power measurement values for the consumer via the correction device 705′ that meet the calibration conditions. The measurement 703 can be used, although only a part of the intrinsic losses is provided, since the sensors 703 are closer to the inductive power transfer. The measurement with sensors 703 decouples PFC losses from the inductive power transfer.

The legally defined error tolerance of a power determination between the measured and corrected power and the actual power must be observed. The errors and losses must be distributed between the power measurement at the input of the power path and the drift and/or tolerance of the components involved in the power path.

The DC power can be determined more accurately than the three-phase 50 Hz input power. If measurements are made more accurately, more tolerance can be allowed for the power elements.

The input power and PFC losses are calibrated separately.

The correction measurement is thus carried out in the calibration range 710b for the determination of a part of the intrinsic power loss P′ᵢₙₜᵣ between the calibrated sensors 204′ of the MVA 104′ and the built-in sensors 703 behind the PFC filter 601. For this purpose, the setting c, E, F is selected on the selection device 707.

If the correction values are stored in the storage unit 705, the GA 105 can independently correct its sensor values, for example, in an autonomous operation. The corrected sensors 703 or the sensor values of the sensors 703 behind the PFC, which are corrected with P′ᵢₙₜᵣ, thus provide a power measurement with a partial compensation of the GA losses, namely the GA losses without the losses of the PFC filter.

$${P}_{cal} ( i ) = P ( i ) - {P}_{intr}^{′} + {P}_{MVA , err}$$

The disturbances or losses taken into account by this calibration method include the partial intrinsic GA losses P′ᵢₙₜᵣ with the power loss P_{conv} of the converter 602, the power loss P_{match} of the impedance matching 603 and the power loss P_{mag} of the magnetic field 106.

$${P}_{intr}^{′} = {P}_{conv} + {P}_{match} + {P}_{mag}$$

FIG. 9 shows an arrangement for calibrating the intrinsic losses of the GA 105 according to an example embodiment of the present invention.

The calibration of the intrinsic losses of the GA 105 serves to determine the overall intrinsic losses Pᵢₙₜᵣ of the GA 105. To determine the intrinsic losses Pᵢₙₜᵣ of the GA 105, an internal power measurement is carried out at the end of the line with the input power measuring device 702 at the input for the voltage supply 107 and is compared with the measured power at the MVA 104′. The power losses P_{MVA,err} of the MVA 104′ are added.

Although the measurement in FIG. 8 can only determine a part of the intrinsic losses with respect to the measurement in FIG. 9, the measurement in FIG. 8 can be useful because the measurement of the sensors 703 is closer to the inductive power transfer. For example, it decouples PFC losses from the inductive power transfer.

The measurement is carried out over the nominal power range, for example a power range from 9.1 kW to 11.1 kW. To cover the power range, a variable load 704 is used on the MVA 104′, which is controlled, for example, by the selection device 707.

The comparison between the power measured with the installed sensors 702 or the input power measuring device 702 with the calibrated sensors 204″ of the MVA 104′ thus results in the correction parameter or correction value, in particular, the disturbance factor, for the intrinsic power loss Pᵢₙₜᵣ as a characteristic curve depending on the input power, with which the sensor values of the input power measuring device 702 must be corrected during the autonomous operation of the GA 105 in order to be able to provide power measurement values for the consumer via the correction device 705′, which meet the calibration conditions.

The correction measurement is thus carried out in the calibration range 710c for the determination of the intrinsic power loss Piner between the calibrated sensors 204′ of the MVA 104′ and the built-in sensors of the input power measuring device 702. For this purpose, the setting b, E, F is selected on the selection device 707.

If the correction values are stored in the storage unit 705, the GA 105 can independently correct its sensor values. The corrected sensor values of the input power measuring device 702 thus provide a power measurement with a compensation of all GA-internal losses, as well as the losses in the magnetic field, also including the losses P_{pfc} in the PFC filter 601, which indicate the power loss of the reactive power correction.

$${P}_{cal} ( i ) = P ( i ) - {P}_{intr} + {P}_{MVA , err}$$

The losses considered by this calibration method comprise the overall intrinsic GA losses Pᵢₙₜᵣ with the power loss P_{pfc} of the reactive power correction, the power loss P_{conv} of the converter 602, the power loss P_{match} of the impedance matching 603 and the power loss P_{mag} of the magnetic field 106.

$${P}_{intr} = {P}_{pfc} + {P}_{conv} + {P}_{match} + {P}_{mag}$$

FIG. 10 shows an arrangement for complete calibration of a power measurement in a GA 105 according to an example embodiment of the present invention.

The complete calibration of a power measurement in a GA 105 essentially comprises the calibration of the input power measurement of a GA 105 according to FIG. 7 and the calibration of the overall intrinsic losses of the GA 105 from FIG. 9.

The complete calibration of a power measurement in a GA 105 is carried out at the end of the line in two steps. In a first step, the internal measurement of the input power by the sensors 702 of the GA 105 is compared with a calibrated power measuring device 701 and thus the input power measuring device 702 is calibrated by determining the correction power parameter P_{GA,err}. In a second step, the overall intrinsic power loss Pᵢₙₜᵣ is determined, as well as the power loss P_{mag} of the magnetic field 106 and the internal power measurement are calibrated.

The correction parameters P_{GA,err}, Pᵢₙₜᵣ, P_{mag} or disturbance factors P_{GA,err}, Pᵢₙₜᵣ; P_{mag} can be stored in the storage unit 705 and used by the correction device 705′ to provide corrected sensor values during the autonomous operation of the GA 105 and thus enable a calibrated input power measurement P(i) with a compensation of all GA-internal and magnetic field losses.

The calibrated power is thus given as

$${P}_{cal} ( i ) = P ( i ) - {P}_{GA , err} - {P}_{intr} + {P}_{MVA , err}$$

Thus, the input power measuring device 702 built into the GA 105 can provide values for the power measurement which are based on a calibrated power measurement at the input of the GA 105 and essentially contain no intrinsic losses of the primary side 105. Thus, all losses for which the energy supplier and operator of a GA 105 is responsible are deducted from the power provided P_{cal}(i). The power P_{cal}(i) can be displayed on a display device 711 and corresponds to the power assigned to the consumer.

Any additional losses which might occur during charging station operation are then caused by the secondary side and are attributed to the consumer. This method is technically and economically feasible and at the same time meets the requirements of the calibration law P_{cal} is the power delivered to the consumer including all losses attributable to the consumer.

The correction measurement is therefore carried out in the calibration range 710a′ for the determination of P_{GA,err} between the calibrated sensors 701 and the input sensors 702. For this purpose, the setting A, b, F is selected on the selection device 707.

The correction measurement is carried out in the calibration range 710c′ for the determination of the intrinsic power loss Pᵢₙₜᵣ between the calibrated sensors 204′ of the MVA 104′ and the built-in sensors of the input power measuring device 702. For this purpose, the setting b, E, F is selected on the selection device 707.

The order in which both steps are carried out is arbitrary and can be swapped.

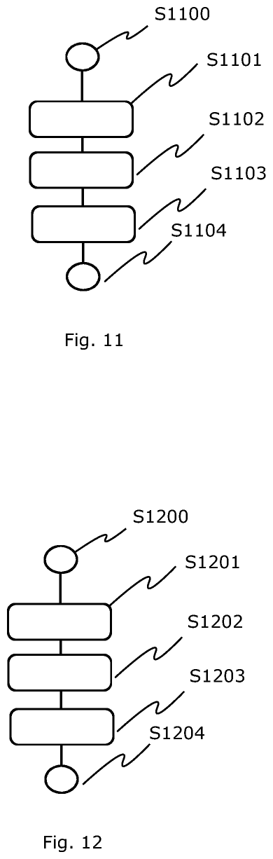

FIG. 11 shows a flow chart for a method for determining a measurement error in a primary-side charging plate when providing energy to a secondary charging plate according to an example embodiment of the present invention.

The method starts in state S1100 in an idle mode.

In state S1101, at least one component to be corrected is selected in the primary-side charging plate, wherein the at least one component to be corrected is influenced by at least one disturbance factor selected from the group of disturbance factors consisting of a measurement error with respect to a comparison value, an intrinsic partial loss, an intrinsic loss and a loss from the secondary charging plate.

In state S1102, the method continues with determining an overall disturbance factor of the respective individual disturbance factors, for example, measurement errors and losses, of the at least one component to be corrected or of the faulty or loss-affected component and determining a correction value from the overall disturbance factor.

In state S1103, the overall disturbance factor is written as a correction value into a storage unit of the primary-side charging plate.

The method ends in state S1104.

FIG. 12 shows a flow chart for methods for calibrated measuring of the energy provided for a secondary-side charging plate 104 in a primary-side charging plate 105 according to an example embodiment of the present invention.

The method starts in state S1200 in an idle mode.

In state S1201, an input power P(i) is determined at the primary-side charging plate 105.

In state S1202, a correction value is read from a storage unit of the primary-side charging plate, wherein the correction value corrects at least one disturbance factor of at least one component of the primary-side charging plate to be corrected, wherein the disturbance factor is selected from the group of disturbance factors consisting of a measurement error P_{GA,err} with respect to a comparison value, intrinsic partial loss P′ᵢₙₜᵣ, an intrinsic loss Pᵢₙₜᵣ and a loss from the secondary charging plate P_{MVA,err}.

In state S1203, an error-corrected or calibrated measurement value P_{cal}(i) is provided.

The method ends in state S1204.

In addition, it is to be noted that “comprising” and “having” do not exclude any other elements or steps and that “one” or “a” does not exclude a plurality. Furthermore, it is to be noted that features or steps that have been described with reference to one of the above example embodiments can also be used in combination with other features or steps of other example embodiments described above. Reference signs in the claims are not to be regarded as a limitation.

### LIST OF REFERENCE NUMERALS

100 inductive charging system
100′ inductive charging system with GA and measuring probe
101 radio connection
102 vehicle chassis
103 floor
104 Vehicle Assembly
104′ measuring probe
105 Ground Assembly
106 magnetic field
107 mains connection
201 coil holding device
202 coil
203 coil positioning device
204 measuring device box
204′ load
204″ measuring instruments
601 PFC filter
602 converter
603 primary-side impedance matching network
604 secondary-side impedance matching network.
605 rectifier
606 primary-side HVDC circuit
607a primary circuit capacitors
607b secondary capacitors
608 secondary-side HVDC circuit
L1 primary coil
L2 secondary coil
701 calibrated power meter
702 input power measuring device
703 sensors behind the PFC filter
705 storage unit
705° correction device
706 compensation device
707 selection device
708 evaluation device
709 writing device
710a, 710a′ calibration range for the determination of P_{GA,err}
710b calibration range for the determination of P′ᵢₙₜᵣ
710c, 710c′ calibration range for the determination of Pᵢₙₜᵣ
711 display device
S1100-S1104 states of a method
S1200-S1204 states of a method

1. A method of determining a correction value for an energy measurement in a primary-side charging plate when providing energy to a secondary charging plate, the method comprising:
selecting at least one component to be corrected in the primary-side charging plate;
wherein the at least one component to be corrected is influenced by at least one disturbance factor selected from the group of disturbance factors consisting of:
a measurement error (P_{GA,err}) with respect to a comparison value;
an intrinsic partial loss (P′ᵢₙₜᵣ);
an intrinsic loss (Pᵢₙₜᵣ); and
a measurement loss (P_{MVA,err}) from the secondary charging plate;
determining an overall disturbance factor of the respective disturbance factors of the at least one component to be corrected;
determining the correction value from the overall disturbance factor; and
writing the overall disturbance factor as a correction value to a storage unit of the primary-side charging plate.

2. The method of determining a correction value according to claim 1, wherein the correction value is a correction curve.

3. The method of determining a correction value according to claim 1, wherein the at least one disturbance factor is determined by an input power measurement at the primary charging plate.

4. The method of determining a correction value according to claim 1, wherein the at least one disturbance factor is determined by a magnetic field measurement in a magnetic field caused by the primary charging plate.

5. A compensation device to determine a correction value for an energy measurement in a primary-side charging plate and to write the correction value to the primary-side charging plate, the device comprising:
a selection device;
an evaluation device;
a writing device;
wherein the selection device is set up to select at least one component to be corrected in the primary-side charging plate;
wherein the at least one component to be corrected is influenced by at least one disturbance factor selected from the group of disturbance factors consisting of:
a measurement error (P_{GA,err}) with respect to a comparison value;
an intrinsic partial loss (P′ᵢₙₜᵣ);
an intrinsic loss (Pᵢₙₜᵣ); and
a measurement loss (P_{MVA,err}) from the secondary charging plate;
wherein the evaluation device is set up to determine an overall disturbance factor of the respective disturbance factors of the at least one component to be corrected;
wherein the evaluation device is set up to determine the correction value from the overall disturbance factor; and
wherein the writing device is set up to write the overall disturbance factor as a correction value to a storage unit of the primary-side charging plate.

6. A method of calibrated measurement of energy provided for a secondary-side charging plate in a primary-side charging plate, the method comprising:
determining an input power (P(i)) at the primary-side charging plate;
reading out a correction value from a storage unit of the primary-side charging plate;
wherein the correction value corrects at least one disturbance factor of at least one component of the primary-side charging plate to be corrected, wherein the disturbance factor is selected from the group of disturbance factors consisting of:
a measurement error (P_{GA,err}) with respect to a comparison value;
an intrinsic partial loss (P′ᵢₙₜᵣ);
an intrinsic loss (Pᵢₙₜᵣ); and
a measurement loss (P_{MVA,err}) from the secondary charging plate; and
providing a calibrated measurement value (P_{cal}).

7. A primary-side charging plate for calibrated measurement of the energy provided for a secondary-side charging plate, the primary-side charging plate comprising:
an input power measuring device;
a storage unit;
a correction device;
wherein the input power measuring device is set up to determine an input power at the primary-side charging plate;
wherein the correction device is set up to read out a correction value from the storage unit of the primary-side charging plate;
wherein the correction value corrects at least one disturbance factor of at least one component of the primary-side charging plate to be corrected, wherein the disturbance factor is selected from the group of disturbance factors consisting of:
a measurement error (P_{GA,err}) with respect to a comparison value;
an intrinsic partial loss (P′ᵢₙₜᵣ);
an intrinsic loss (Pᵢₙₜᵣ); and
a measurement loss (P_{MVA,err}) from the secondary charging plate;
wherein the correction device (705′) is for providing a calibrated measurement value (P_{cal}).

8. A measuring probe for a magnetic field measurement, the probe comprising:
a coil;
a coil holding device;
a coil positioning device;
wherein the coil holding device is set up to hold the coil in a magnetic field;
wherein the coil positioning device is set up to position the coil in the magnetic field such that the coil experiences a large and/or maximum coupling with the magnetic field.

9. The measuring probe according to claim 8, wherein the coil positioning device further comprises:
a locking element;
wherein the locking element is set up to lock into the housing of a primary-side charging plate in order to bring about the large and/or maximum coupling with the magnetic field.

10. The measuring probe according to claim 8, wherein the coil holding device is formed as a table.
